(19) United States
(12) Patent Application Publication
(10) Pub. No.: US 2014/0125332 A1
(43) Pub. Date: May 8, 2014

(54) MAGNETOSTRICTIVE LAYER SYSTEM

(71) Applicants: Enno Lage, Kiel (DE); Dirk Meyners, Moenkeberg (DE); Eckhard Quandt, Heikendorf (DE)

(72) Inventors: Enno Lage, Kiel (DE); Dirk Meyners, Moenkeberg (DE); Eckhard Quandt, Heikendorf (DE)

(73) Assignee: CHRISTIAN-ALBRECHTS-UNIVERSITÄT ZU KIEL, Kiel (DE)

(21) Appl. No.: 14/128,927

(22) PCT Filed: Jun. 20, 2012
(86) PCT No.: PCT/EP2012/061860

§ 371 Date: Jan. 7, 2014

(30) Foreign Application Priority Data
Jun. 24, 2011 (EP) 11171354.1

(51) Int. Cl. G01R 33/02; H01L 41/47

(52) U.S. Cl. CPC G01R 33/02; H01L 41/47
USPC 324/244; 428/811.2; 29/25.35

(57) ABSTRACT

A magnetostrictive layer system is suggested comprising at least one layer sequence comprising an anti-ferromagnetic, (AFM), layer and a magnetostrictive, ferromagnetic, FM, layer arranged directly thereon, wherein the layer sequence has an associated exchange bias, EB, field, the EB-induced degree of magnetization of the FM layer in the absence of an external magnetic field being within a range between 85% and 100%, and the angle αₒₚₜ, which is enclosed by the EB field direction and the magnetostriction direction, that has the maximum piezomagnetic coefficient in the absence of an external magnetic field, within a plane parallel to the AFM layer and the FM layer lies within a range between 10° and 80°.

### FIELD OF THE INVENTION

The invention relates to a magnetostrictive layer system and a method for its production. The invention also relates to magnetoelectric sensors.

### BACKGROUND OF THE INVENTION

The magnetostriction of a material designates its change of shape and/or volume under the action of an external magnetic field. In the case of a change of shape, this is expressed by a change in length in the direction of the applied magnetic field that is accompanied by a change in length perpendicular to the field direction (Joule magnetostriction), that maintains the volume. The length can increase or decrease in the field direction as a function of the material, which is termed positive or negative magnetostriction.

In principle, magnetostriction can also be assumed in the case of all ferromagnetic or ferrimagnetic materials. For some, the extent of the magnetostriction is large enough that they achieved technical importance as “magnetostrictive materials”. As examples, ferromagnetic transition materials (Fe, Ni, Co) and their alloys, compounds of the rare earths Tb, Dy, Sm with the ferromagnetic transition metals (e.g. TbFe₂, SmFe₂, TbDyFe) or also ferromagnetic glasses that predominantly contain the elements Fe, Co, B or Si in varying fractions, so-called magnetic met glasses, shall be mentioned.

The alignment of magnetic elementary dipoles along the external magnetic field is regarded as the cause of the magnetostrictive change in length. According to what is known at present, it can amount to up to 2.5 mm/m=2500 ppm at room temperature. However, elongation to a greater extent up to approximately 10% is achieved in ferromagnetic shape-memory alloys by field-induced reorientation of martensite variants.

As a matter of principle, magnetostriction does not take place as a linear function of the external magnetic field strength. Rather there exists e.g. a saturation field strength H_{S} beyond which no further change in length of the material can be detected. All elementary dipoles have then already aligned completely in the field direction, and a further increase in the field strength does no longer cause any reaction of the material.

Furthermore, magnetostriction is invariant to field reversal, i.e., at the same starting configuration of the magnetization and without taking into account hysteresis effects, two fields having the same field strength that point in opposite directions exhibit the same change in length.

The magnetostriction curve λ(H) describes the magnetostrictive change in length of a material (or of a body from the material) along the magnetic field direction having a field strength H on account of a change in the domain distribution in the material.

In the simplest case without magnetic hysteresis, λ(H) goes through the origin (no change without a field) and symmetric to H=0. For large absolute values of H (>|H_{S}|), it assumes a (positive or negative) saturation value. Its derivative dλ/dH that is called the “piezomagnetic coefficient” in the literature, exhibits between H=0 and H=±H_{S} two extreme values that amount to H=±H_{B}. Consequently it is there that inflection points of the magnetostriction curve are situated, and in the surroundings of these inflection points—that is for small field variations about H=±H_{B}—the magnetostriction is approximately linear and of maximum sensitivity.

Normally, magnetostrictive materials also exhibit a more or less pronounced hysteresis, and thus the course of the magnetostriction curve also depends on the history. In particular when cycling in an external field, it is found that there is a difference whether a specific field strength H₀ is being approached from larger or smaller fields. There exist two measurable changes in length λ<(H₀) and λ>(H₀) that, however, also show a symmetry to H=0: λ<(H₀)=?>(−H₀) and λ<(−H₀)=λ>(H₀).

For example it is known from US 2004/0126620 A1 to produce multi-layered composite materials from magnetostrictive and piezoelectric material layers, so-called magnetoelectric composite layers. Among others, they are very well suited to transfer the change in length of the magnetostrictive material, on account of the mechanical coupling, onto the piezoelectric material and there to cause a change in the electric polarization state. The charge shift (piezo effect) caused by the structure generates a measurable electric field or a measurement voltage that detects directly the magnetostriction and thus indirectly the external magnetic field. Such a composite can form the basis of a magnetic-field sensor that is usually called a magnetoelectric sensor or ME sensor for short.

If very small magnetic fields are to be detected, that is to say very sensitive magnetostrictive layers are to be produced, a sufficient amount of magnetostrictive material has to be provided for this purpose. All the expert knowledge states that material volumes in the order of magnitude of cubic millimeters are appropriate for detecting pico-Tesla flux densities. To produce an “exchange-biased” ME sensor for small fields at first does not look promising using magnetostrictive layer thicknesses that are to be limited to a few dozen nanometers according to what has been said above.

The term “piezomagnetic coefficient in the zero field” is to be used below to characterize a magnetostrictive layer. In the sense of the present description this means the absolute value of dλ/dH in the absence of an external magnetic field, or in the zero field for short.

The object of the invention is to specify a magnetostrictive layer system that is suitable to manufacture extremely sensitive ME sensors.

The object is achieved by a layer system comprising at least one anti-ferromagnetic (AFM) layer and a magnetostrictive, ferromagnetic (FM) layer arranged directly thereon and exhibiting an exchange-bias (EB) field, characterized by an EB-induced degree of magnetization of the FM layer in the zero field over 85% and under 100% and an angle αₒₚₜ in the layer plane which is enclosed by the EB field direction and the magnetostriction direction, that has the maximum piezomagnetic coefficient in the zero field, that is between 10° and 80°. The sub-claims specify advantageous embodiments of the layer.

The maximum piezomagnetic coefficient mentioned above lies within the same order of magnitude as the piezomagnetic coefficient of a magnetostrictive layer of the same material, that is conventionally supported by permanent magnets.

The invention is now based on the finding that in the zero field the piezomagnetic coefficient is a function of the direction in the FM layer along which magnetostriction is to take place (magnetostriction direction) if prior to this a magnetic anisotropy has been introduced by an EB field. In this respect, the piezomagnetic coefficient in the zero field is a function of the angle which is enclosed by this direction and the EB field direction in the layer plane. It assumes a maximum for a direction that matches significantly neither the EB field direction, nor is arranged at right angles to the EB field direction. This direction can be identified by measuring the maximum piezomagnetic coefficient.

The degree of magnetization is explained as the ratio M(H)/M(H_{S}), M(H) specifying the magnetization that can be measured in the external field H and M(H_{S}) specifying the saturation magnetization. Consequently, the degree of magnetization in the zero field is M(H=0)/M(H_{S}).

The inventive layer system exhibits the characteristic 0.85<M(H=0)/M(H_{S})<1 and thus exhibits a net magnetization of the at least one FM layer (magnetic layer moment). The degree of magnetization can be measured by first determining the direction and the absolute value of the layer moment and then recording a magnetic hysteresis curve along this direction. The direction of the layer moment is at the same time the direction of the impressed exchange-bias field.

An inventive layer system is characterized by a hysteresis curve in the exchange-bias field direction which on one side of the ordinate H=0 already exhibits an approximately complete magnetization. In particular, even in the zero field the at least one magnetostrictive FM layer is already at least 85% magnetized by exchange bias. However, it is not supposed to be completely magnetized since this would already amount to an EB pinning that is so strong that the lack of mobility of the elementary magnets would have a harmful effect on the intended magnetostriction. Thus the choice of the absolute value of the EB field H_{EB} set up according to the invention in the layer system has an upper limit.

The inventive layer system exhibits the maximum piezomagnetic coefficient in the zero field along a direction in the layer plane that with the direction of the EB field encloses the angle αₒₚₜ, αₒₚₜ being between 10° and 80°. A preferred embodiment can be seen in the fact that the angle αₒₚₜ lies between the angles 45° and 75°. The angle is determined indirectly by the absolute value of the EB field. The angular limit mentioned insofar represents an advantageous limitation of H_{EB}.

Using the inventive layer system, in particular an ME sensor can be produced that exhibits an immanent supporting field and a high piezomagnetic coefficient and also a high magnetoelectric voltage coefficient in the zero field, but only a small stray field or even no stray field at all. Such an ME sensor exhibits a predetermined measuring direction that essentially encloses the angle αₒₚₜ with the direction of the EB field of the layer system. This angle is at least 10° and at most 80°. Preferably it amounts to between 45° and 75°.

To produce the ME sensor, it is also possible to deposit the inventive layer system within the framework of the expert knowledge a plurality of times on top of each other and thus form a layer stack. It can be advantageous to provide non-magnetic intermediate layers between the repetitions of the AFM/FM bilayers with the inventively set exchange bias. The purpose of the intermediate layers will be explained further below.

### SHORT DESCRIPTION OF THE FIGURES

The invention will be explained in more detail below also using the following figures. In the figures:

FIG. 1 shows the hysteresis curve of a layer stack comprising magnetostrictive layers supported by exchange bias (EB) in the direction of the EB field;

FIG. 2 shows the magnetostriction curves of the layer stack from FIG. 1 for different angles between the magnetic field and the EB field direction that illustrate the angular dependence of the piezomagnetic coefficient;

FIG. 3 shows a calculated comparison of stray fields between an EB-supported and a permanent-magnetically supported magnetostrictive layer.

FIG. 4 shows a layer system according to an exemplary embodiment of the invention;

FIG. 5 shows a magnetoelectric sensor according to an exemplary embodiment of the invention;

FIG. 6 shows a flow chart of a method according to an exemplary embodiment of the invention.

### DETAILED DESCRIPTION OF EXEMPLARY EMBODIMENTS

An important aspect of the sensitivity of ME sensors is the extent of the magnetostriction to small magnetic fields (smaller than nano Tesla, 1 Tesla=μ0×10,000 Oersted). A second aspect is the linearity of the voltage response to changes in the magnetic field. Both are optimized in the sense of the measurement task if the magnetostrictive layer of the composite can be successfully arranged such that it exhibits, for a very small magnetic field to be measured, a comparable piezomagnetic coefficient dλ/dH as is usually the case in the area of the inflection points of the magnetostriction curve.

It can be advantageous to arrange a so-called supporting field alongside the layer. The supporting field is to be temporally constant and, in the area of the sensor, homogenous and extend along the direction in which the magnetostriction is to be optimised. Relative to an ME sensor this is the measuring direction along which one component of the measurement field is to be determined. The supporting field is also called a magnetic bias field and, according to what has been said above, exhibits the absolute value H_{E} in the entire layer as far as possible.

A magnetostrictive layer that is “unsupported” (i.e. not influenced by a supporting field) and that is not pre-magnetized, exhibits a magnetostriction curve symmetrical to H=0 and in the zero field a piezomagnetic coefficient of practically zero. If in contrast a supporting field of the strength H_{B} according to the prior art is set up in the layer, there exists an energetically favored preferable direction for the alignment of the elementary dipoles—a magnetic anisotropy—and the piezomagnetic coefficient is a function of the direction in the zero field. It then assumes its largest value in the direction of the supporting field.

A supporting field can be generated electromagnetically or by arranging permanent-magnetic material. In the case of the electromagnetic generation of a supporting field, new noise sources are introduced that can degrade the signal-to-noise ratio of the sensor arrangement. The deployment of permanent magnets that are arranged directly at the edges or even inside the magnetostrictive layer, permits the production of so-called “self-biased” ME sensors that can detect very small measurement fields (see also e.g. EP 0 729 122 A1).

However, all magnetostrictive layers known at present having a “self-bias” (immanent supporting field) exhibit a net magnetization different from zero and thus also generate magnetic stray fields in their surroundings. This is a disadvantage in particular if a plurality of magnetostrictive elements is arranged in close proximity, for example in an ME sensor array for spatially resolved magnetic-field measurement. In addition, the monolithic integration of sensor and supporting-field generator presents an additional hurdle for miniaturization. Any movement of the sensor relative to the supporting-field arrangement would further result in another noise source on account of even smallest field inhomogeneities.

ME sensor arrays are good candidates for a new generation of biomagnetic detectors that could soon replace the previous SQUID technology in important areas of application. For example, the magnetic fields of cardiac currents or also brain waves can be detected—preferably spatially resolved and using different field components—on a test person and, in principle, also be calculated back to the generating current distribution (source reconstruction). In future, even the control of devices (e.g. prostheses) can be envisaged by means of the magnetically detected brain wave patterns. Superconducting SQUIDs however rely on extreme cooling, while ME sensors achieve sensitivity values into the pico-Tesla range even at room temperature. The problem of mastering the stray fields still remains to be solved.

The work by Vopsaroiu et al., “A new magnetic recording read head technology based on the magneto-electric effect”, J. Phys. D: Appl. Phys. 40 (2007) 5027-5033, reveals the suggestion to read out magnetic storage media via miniaturized ME sensors instead of via the magnetoresistance according to the prior art.

It is possible that the relatively large magnetic moments impressed in the storage medium (whose orientations represent the bits) can cause a piezoelectrically measurable change in length even in a very thin layer of magnetostrictive material. For this reason the magnetostrictive layer should to be brought into a favorable operating point. This can be achieved by the exchange interaction using an anti-ferromagnetic (AFM) layer that is arranged directly on top of or below the magnetostrictive ferromagnetic (FM) layer.

The FM/AFM exchange interaction is termed “exchange bias” (EB) in the literature and has been investigated theoretically and experimentally in depth since its discovery in 1956. Until now there exists no general model on how it comes about, but it is considered an established fact that it is an interface effect between AFM and FM phases. As such, the EB effect has a short range that is essentially determined by the magnetic exchange length (in most materials a few up to a few dozen nanometers).

The EB effect is utilized above all for the so-called “pinning” of magnetic layers in digital storage technology, for example when manufacturing “magnetic tunnel junctions” for “magnetic random access memory” (MRAM) or magnetic read heads. By “pinning”, a magnetization of an FM layer that has been established once is fixed or stabilized. This takes place for example by cooling down an FM/AFM bilayer in the magnetic field (“field annealing”), the temperature at first falling below the Curie temperature so as to fix the alignment of the dipoles in the FM layer. Also the dipoles of the AFM layer align on further cooling down below the Neel temperature and thus produce a magnetic, unidirectional anisotropy in the FM layer. Twisting or flipping-over of the dipoles in the FM layer is made more difficult as a result which is most obvious in a shift of the magnetic hysteresis curve along the anisotropy. The extent of the shift H_{EB} is referred to as exchange bias field (strength).

Further information on exchange bias and extensive tables (in particular the tables 2-4) using anti-ferromagnetic materials can be gathered for example from the overview article of the same name by Nogués and Schuller (Journal of Magnetism and Magnetic Materials 192 (1999) 203-232).

The concept for a magnetic read head that dispenses with a test current for measuring the magnetoresistance is very attractive for mobile computers that rely on limited energy cells.

Evidently no ME sensors are known that exhibit an AFM based supporting field. Since “self-biased” ME sensors are investigated above all for detecting very small magnetic fields, this is not surprising, for some problems can be expected when implementing the concept:

The EB effect is the bigger, the thinner the magnetostrictive FM layer. A very thin FM layer is usually completely pinned in one direction using an H_{EB} well in the order of magnitude of several 100 Oe. A layer that is pinned in this way in practice no longer exhibits any magnetostriction for relevant magnetic fields, none less so in the pinning direction.

As is known, H_{EB} decreases with an increase in the layer thickness of the FM layer. An FM layer can exhibit in the vicinity of the AFM/FM interface an area that is favorably arranged for the magnetostriction. Layer areas further away are, however, not reached by EB. To achieve a homogenous magnetization in the FM layer using EB it is thus not favorable to select the thickness of the FM layer too large.

Magnetostrictive layers are used for actuators or in combination with piezoelectric layers as magnetoelectric sensors. In both cases, the size of the effect (actuator) or the sensitivity (magnetoelectric sensor) scales with the layer thicknesses of the magnetostrictive layers.

The starting point of the invention is the finding that the absolute value of the EB field that is set up in an AFM/FM bilayer, according to present knowledge cannot in general be predicted theoretically, but can only be determined by experiments later using the magnetic hysteresis curve. Only the direction of the EB field can be set accurately in advance by choosing the direction of the annealing field. However, the absolute value of the EB field can be altered by varying the layer thickness of the FM layer; it decreases when the layer thickness increases.

If at first Vopsaroiu et al. are adopted, an EB field would have to be generated whose absolute value H_{EB} corresponds precisely to the supporting-field strength H_{E} for which the piezomagnetic coefficient becomes a maximum, so as to set the sensitivity in the direction of the EB field. However, H_{EB} and H_{E} cannot be varied independently of each other since both change with the thickness of the FM layer, and it is not clear whether the condition H_{EB}=H_{E} can at all be fulfilled for any layer thickness and, if this can be done, how complicated is the practical implementation.

A core aspect of the invention is therefore to create an AFM/FM layer system comprising a magnetostrictive FM layer that can be brought into a defined magnetic state by an EB field and then to look for magnetostriction along another direction in the layer plane than that of the EB field. This reveals a direction that is characterized by maximum piezomagnetic coefficients in the zero field and which encloses an angle αₒₚₜ with the EB field direction that lies between 10° and 80°. αₒₚₜ preferably lies between 45° and 75°.

The inventive layer system can be produced using a physical vapor deposition method such as for example sputtering.

According to the prior art, the thickness of the AFM layer can be selected such that a further increase in the AFM layer thickness no more influences the absolute value of the EB field in the FM layer. Usually a layer thickness of a few nanometers is sufficient for this. However, the AFM layer thickness can also be selected to be smaller if only it can form a stable anti-ferromagnetic phase. The prior art strives for the maximum possible EB fields to pin FM layers. In the present invention, however, an EB field strength having an upper limit is convenient. The thickness of the FM layer determines the exchange-bias field strength H_{EB}.

By preliminary experiments, the person skilled in the art can easily obtain clarity on the question whether an exchange bias in the sense of the invention can be set up for a specific choice of material of the AFM/FM layer system and which layer thicknesses are necessary to achieve this.

He can for example produce a set of samples having differing FM layer thicknesses, but else identically prepared AFM layers, anneal them under identical conditions in the magnetic field one after the other at Curie and Neel temperature and then record the hysteresis curves for example using a vibrating sample magnetometer along the annealing direction.

It is to be recommended to expose the samples in the annealed state at first to some magnetic polarization reversals to account for the so-called training effect of the exchange bias. As a result, the EB field is brought to a stable final value during the course of a few cycles.

The examination of the hysteresis of the samples should then result in at least one, conventionally several hysteresis curves that indicate that one or more samples are already in the zero field in the vicinity of the magnetic saturation. According to the invention, a minimum degree of magnetization of 85% is requisite for a defined magnetic state.

A sample that is preferred according to the invention is that one where it is just this what happens, that exhibits the smallest EB field in terms of absolute value that is sufficient for a magnetization of at least 85% of the FM layer of the sample in the zero field. As a result of this limitation, the EB field is not of such a size that the dipoles would no longer be mobile and could no longer be influenced by small magnetic fields. Suitable layer thicknesses can be directly derived for the inventive layer system from the described preliminary investigation.

As a first exemplary embodiment, an inventive layer system can be realized as follows:

A 2 nm thick tantalum layer and a 2 nm thick copper layer arranged thereon form a seed layer for the anti-ferromagnet. On it, an AFM layer from Mn₇₀Ir₃₀ (at %) that in general preferably has a thickness between 3 nm and 8 nm, particularly preferably and here as an example 5 nm, is deposited. The magnetostrictive FM material Fe₅₀Co₅₀ is arranged on the AFM layer in a layer that in general preferably has a thickness between 15 nm and 25 nm, particularly preferably and here as an example 20 nm.

It is to be noted here that on the one hand there exist polycrystalline AFM materials that form an AFM phase on virtually any substrates, and on the other hand those that require for this purpose a specific crystalline order (“texture”) of the substrate. If this is not present, this can be circumvented by arranging an additional seed layer. In the exemplary embodiment, the nano-crystalline tantalum has the task of “erasing” the texture of the substrate or to make it invisible for the materials arranged there above. The copper layer deposited thereon then provides a favorable substrate for forming the AFM phase in the manganese-iridium alloy.

The layer system of the exemplary embodiment can exhibit the same choice of materials as it is described in the work of G. Reiss, D. Meyners, “Logic based on magnetic tunnel junctions”, J. Phys.: Condens. Matter 19 (2007), 165220 (12 pp).

The layer system of the first exemplary embodiment can by repetition be formed as a layer stack since the “texture-erasing” effect of the tantalum also occurs during the repetitions of the layer sequence. In all repetitions, the tantalum is arranged on a magnetostrictive FM layer.

As a second exemplary embodiment, a magnetostrictive layer stack having a total of 40 repetitions of the Ta/Cu/Mn₇₀Ir₃₀/Fe₅₀Co₅₀ layer system is realized—as described in the first exemplary embodiment. It exhibits a total thickness of 1200 nm, two thirds of the volume being formed by magnetostrictive material. Thus approximately 10⁸ μm³ of magnetostrictive material per square centimeter cross-sectional surface can be deposited on a substrate which is within the frame of the conventional design of highly-sensitive ME sensors that are produced by means of thin film technologies.

An inventive layer system can be produced by coating a substrate (e.g. silicon wafer) and then detaching it from the substrate as a whole. It can thus be formed without any substrate.

In the following overview table, further material systems suitable for realizing the invention are listed. The layer thicknesses (in particular for setting H_{EB}) and angles relative to the EB field direction having a maximum piezomagnetic coefficient in the zero field can be determined with the aid of samples, as described further above. The subscripts behind the elements in the table designate the mixing ratios in atom per cent (at %). Further remarks can be gathered from the footnotes of the table.

Examples for inventive layer systems^{a}

| | | Magnetostrictive |
|---|---|---|
| | | layer or |
| Seed layer or seed- | Anti-ferromagnetic | magnetostrictive |
| layer system^{b} | layer | layer system^{b} |
| Ta/Cu | Mn₇₀Ir₃₀^{c} | Co₅₀Fe₅₀^{d} |
| Ta/Cu | Mn₇₀Ir₃₀^{c} | Co₄₀Fe₄₀B₂₀^{f} |
| Ta/Cu | Mn₇₀Ir₃₀^{c} | Co₅₀Fe₅₀^{d}/Co₄₀Fe₄₀B₂₀^{f} |
| Ta/Cu | Mn₇₀Ir₃₀^{c} | Co₅₀Fe₅₀^{d}/ |
| | | Fe₇₀Co₈B₁₂Si₁₀^{g} |
| Ta/Cu | Mn₇₀Ir₃₀^{c} | Co₅₀Fe₅₀^{d}/Tb₃₅Fe₆₅^{d} |
| Ta/Ni₈₀Fe₂₀^{d} | Mn₇₀Ir₃₀^{c} | Co₅₀Fe₅₀^{d} |
| Ta/Ni₈₀Fe₂₀^{d} | Mn₇₀Ir₃₀^{c} | Co₄₀Fe₄₀B₂₀^{f} |
| Ta/Ni₈₀Fe₂₀^{d} | Mn₇₀Ir₃₀^{c} | Co₅₀Fe₅₀^{d}/Co₄₀Fe₄₀B₂₀^{f} |
| Ta/Ni₈₀Fe₂₀^{d} | Mn₇₀Ir₃₀^{c} | Co₅₀Fe₅₀^{d}/ |
| | | Fe₇₀Co₈B₁₂Si₁₀^{g} |
| Ta/Ni₈₀Fe₂₀^{d} | Mn₇₀Ir₃₀^{c} | Co₅₀Fe₅₀^{d}/Tb₃₅Fe₆₅^{d} |
| Ta | Mn₇₀Ir₃₀^{c} | Co₅₀Fe₅₀^{d} |
| Ta | Mn₇₀Ir₃₀^{c} | Co₄₀Fe₄₀B₂₀^{f} |
| Ta | Mn₇₀Ir₃₀^{c} | Co₅₀Fe₅₀^{d}/Co₄₀Fe₄₀B₂₀^{f} |
| Ta | Mn₇₀Ir₃₀^{c} | Co₅₀Fe₅₀^{d}/ |
| | | Fe₇₀Co₈B₁₂Si₁₀^{g} |
| Ta | Mn₇₀Ir₃₀^{c} | Co₅₀Fe₅₀^{d}/Tb₃₅Fe₆₅^{d} |
| TaN/Ta | Pt₅₀Mn₅₀^{e} | Co₅₀Fe₅₀^{d} |
| TaN/Ta | Pt₅₀Mn₅₀^{e} | Co₅₀Fe₅₀^{d}/Co₄₀Fe₄₀B₂₀^{f} |
| TaN/Ta | Pt₅₀Mn₅₀^{e} | Co₅₀Fe₅₀^{d}/ |
| | | Fe₇₀Co₈B₁₂Si₁₀^{g} |
| TaN/Ta | Pt₅₀Mn₅₀^{e} | Co₅₀Fe₅₀^{d}/Tb₃₅Fe₆₅^{d} |
| Ta/Cu/NiFe | Fe₅₀Mn₅₀^{h} | Contained in the |
| | | seed-layer system |

^{a}The layer systems are formed by the materials mentioned in the rows. Here the stack sequence is given by seed layer, anti-ferromagnetic layer and magnetostrictive layer. The layer systems can be deposited on each other, repeated several times.
^{b}Seed layers or magnetostrictive layers can also consist of several individual layers from different materials. In the table, such individual layers are separated from each other by the character/. The first-mentioned individual layer is also deposited first, so that the notation represents the stack sequence.
^{c}MnIr must be present in the anti-ferromagnetic phase which can for example be achieved for the specified alloy composition in atom percent in an manner known per se. All compositions between Mn₇₀Ir₃₀ and Mn₈₀Ir₂₀ are suitable for the inventive layer system.
^{d}Preferred alloy composition in atom percent
^{f}Preferred alloy composition in atom percent; the boron content should amount to approximately twenty atom percent to generate an amorphous layer.
^{g}Preferred alloy composition in atom percent; the content of glass formers (boron and silicon) should amount to about twenty atom percent to generate an amorphous layer.
^{e}PtMn must be present in the anti-ferromagnetic phase which can be achieved for example for the specified alloy composition in atom percent by heat treatment. All compositions between Pt₃₅Mn₆₅ and Pt₄₄Mn₅₆ are suitable for the inventive layer system.
^{h}Preferred alloy composition in atom percent; FeMn must be present in the anti-ferromagnetic phase.

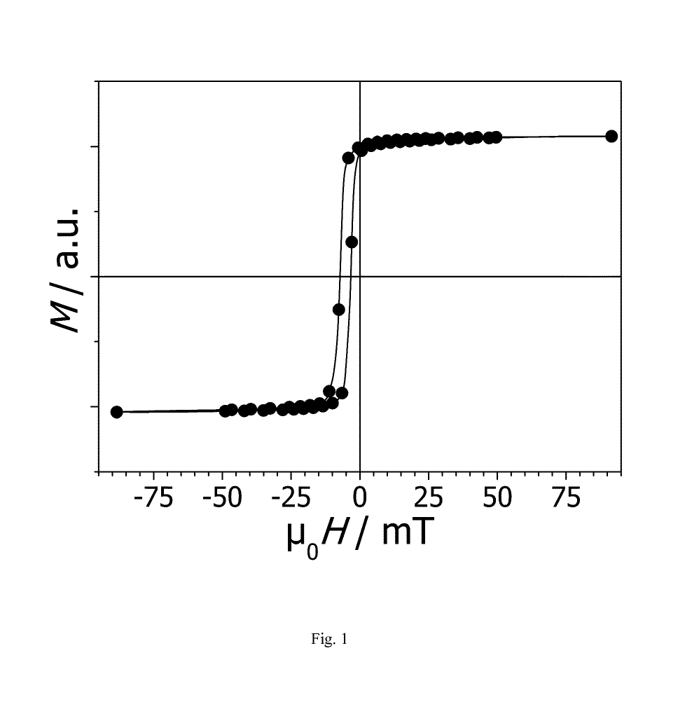

FIG. 1 shows the measured hysteresis curve of the layer stack according to the second exemplary embodiment in the direction of the annealing field that is used when arranging the exchange bias. The presence of a magnetization of at least 85% of the FM layers in the layer stack on one side of the ordinate at H=0 due to the impressed EB field is a characteristic of the inventive layer system.

As has already been mentioned, the person skilled in the art is familiar with the formation of layer stacks. Likewise he for example also knows from US 2011/062955 A1 that ME sensors can be implemented as layer stacks comprising in each case a plurality of magnetostrictive and piezoelectric layers in an alternating sequence. It is therefore also possible to produce ME sensors that exhibit the piezoelectric layers and inventive magnetostrictive layer systems in an alternating sequence.

As an alternative, it is also possible to connect a magnetostrictive layer stack, which is formed as described above as a repetition of the inventive layer system, as a whole to an individual piezoelectric layer so as to create an ME sensor. This possibility is to be preferred on account of the considerably simpler lithographic structuring in the case of metallic/conducting magnetostrictives.

If the magnetostriction of the layer stack according to the second exemplary embodiment is examined at different angles 0<α≦90° relative to the impressed direction of the EB field, it is found that the magnetostriction curve is now shifted as a function of α and also changes its qualitative course.

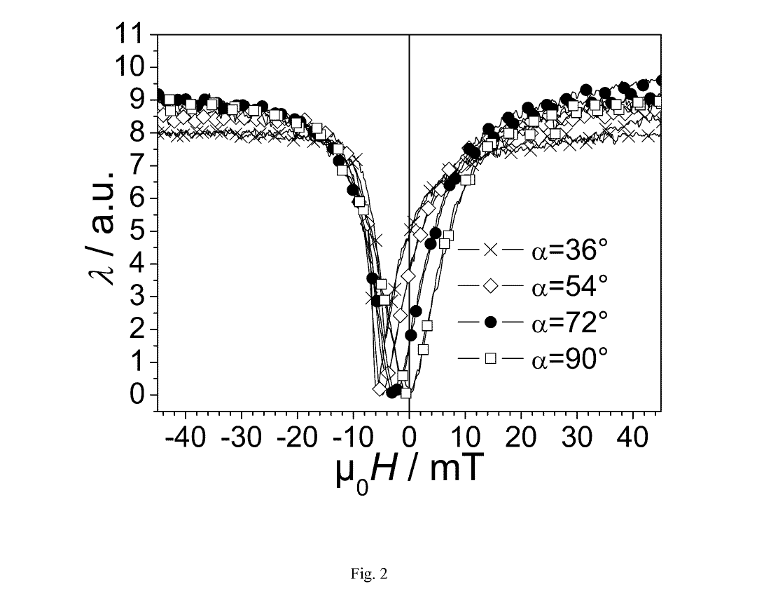

FIG. 2 shows measured magnetostriction curves for the second exemplary embodiment along directions that are rotated relative to the EB direction about the angle αₒₚₜ=36°, 54°, 72° and 90°. The 90°-case here corresponds to the known symmetric behavior of the magnetostriction curve if the dipoles of the FM layer are aligned in particular precisely at right angles to the direction of the magnetic field that effects the magnetostriction. In the other cases, asymmetry and in particular a more or less strong rise dλ/dH can be seen at H=0. Here the direction having the largest piezomagnetic coefficient dλ/dH in the zero field is determined at αₒₚₜ=54°.

The deviation of the direction of the impressed EB field (which direction can be determined at any time using the occurrence of the maximum shift of the hysteresis curve relative to H even after the layer system has been finished) from the direction in the layer plane in which the maximum piezomagnetic coefficient can be measured in the zero field, by an angle αₒₚₜ that lies between 10° and 80°, preferably between 45° and 75°, is a further characteristic of the inventive layer system.

The precise value of the angle αₒₚₜ cannot be specified in general terms, but it must be measured for each specific layer system—when specifying the materials and layer thicknesses—using an angle-resolved examination of the magnetostriction. However, it is to be determined only once for the layer system. If a layer system with slight deviations from one that is already known is produced, an adaptation of αₒₚₜ may be requisite.

Due to the fact that αₒₚₜ can be set subsequently, the precise absolute value of the impressed EB field is not too important. If H_{EB} is set slightly larger than necessary, that is in particular in such a way that the degree of magnetization of the at least one FM layer exceeds 85% in the zero field, the direction having the maximum piezomagnetic coefficient in the zero field is then found at a slightly larger angle αₒₚₜ.

If there are several possibilities—e.g. several samples in the preliminary examinations—for setting an EB field that effects an inventively suitable degree of magnetization of the FM layers in the zero field, it is advantageous to select among these possibilities those that bring the angle αₒₚₜ into the interval between 45° and 75°.

In a manner of speaking, looking for αₒₚₜ corresponds to the fine adjustment of the EB field in the supporting direction. The absence of such a fine adjustment in the case of Vopsaroiu et al. up to now prevented the practical implementation. Using the means described here, “EB field-supported” magnetostrictive layer systems having a high piezomagnetic coefficient in the zero field can now be produced and applied.

To manufacture ME sensors for very small measurement fields, one has to rely on producing EB field-supported layer stacks to have enough magnetostrictive material. The statements on the shifting of the hysteresis curve and the angular dependence of the piezomagnetic coefficients in the zero field equally apply for an individual inventive layer system and also for a layer stack that comprises a plurality of repetitions of the layer system. In fact, it is even easier to measure the hysteresis and magnetostriction on a layer stack. Usually, the EB field is only impressed into the layer stack after it has been finished. Then the angle αₒₚₜ is identified.

In the case of an ME sensor, the substrate is for example conventionally a rectangular strip e.g. from Si or also from a glass that has at first been coated with a piezoelectric material. Also the substrate can be a piezoelectric which itself has been formed in a cantilevered fashion. For example, bottom and top of the composite are contacted using electrodes for tapping the voltage.

An ME sensor also exhibits a determined axis along which the magnetostriction is to be utilized and where for this reason it has to exhibit a maximum sensitivity. In the case of the rectangular strip, this is e.g. the longer axis. After the inventive layer stack has been arranged on the piezoelectric, the supporting field is preferably impressed by annealing in the magnetic field. As an alternative, the intrinsic supporting field can also be generated during the deposition of the magnetostrictive material e.g. by sputtering in a magnetic field. In all cases it is necessary to rotate the magnetic field that determines the direction of the EB field, about the angle αₒₚₜ relative to the determined axis of the ME sensor. In this way, the magnetostrictive layer system exhibits its maximum piezomagnetic coefficient in the zero field in particular precisely along the determined direction, in the example of the strip therefore e.g. along the longitudinal axis and thus the intended measuring direction of the ME sensor.

As an alternative, the layer stack can be applied over a large area e.g. on a two-dimensional substrate (e.g. a wafer) that has been provided in advance with an electrically contacted piezoelectric. The entire wafer can then be treated in the annealing field and then be singulated into strip-shaped ME sensors. In the process, it has to be taken into account that the direction of the singulation—what is meant is the direction of the long axes of the singulated strips—must enclose the angle αₒₚₜ with the annealing field so that the most sensitive ME sensors are obtained.

The magnetostrictive layer system described here has the essential advantage of a strongly reduced net magnetization by eliminating permanent magnets. It is only the anisotropy introduced by exchange bias that takes care that the favorable alignment of the elementary dipoles in each magnetostrictive layer generates a magnetic net moment. However, this is small compared to the field strengths of the permanent magnets that would otherwise be needed for the supporting field. On top of this, the uniformity of the dipole alignment—i.e. the homogeneity of the supporting field—is practically guaranteed by the EB effect which in itself already is an improvement compared to the prior art.

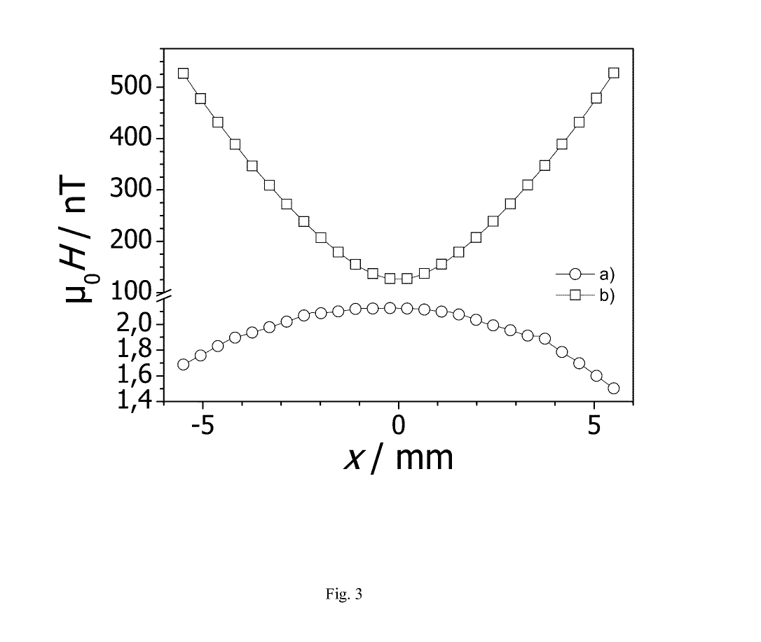

Since stray fields can be measured only with considerable effort, a numerical model calculation shall be sufficient here to illustrate the effect of the invention. FIG. 3 shows the calculated field distribution in the vicinity of a ferromagnetic, magnetostrictive rectangular strip parallel to its longitudinal axis (x-axis) for a) an inventive EB-bias magnetization (with αₒₚₜ=60°, i.e., an AFM strip pins the dipoles at an angle of 60° relative to the longitudinal axis by exchange bias) and for b) a permanent-magnet arrangement with the main field direction along the longitudinal axis. The size of the permanent magnets from AlNiCo has been selected such that their magnetic field on average amounts to 5 Oe at the location of the ferromagnetic rectangular strip and does not vary by more than ±10%. The magnetic fields in the center (x=0) of a second, neighboring rectangular strip or sensor amount in case a) to approximately 2 nT and in case b) to approximately 100 nT.

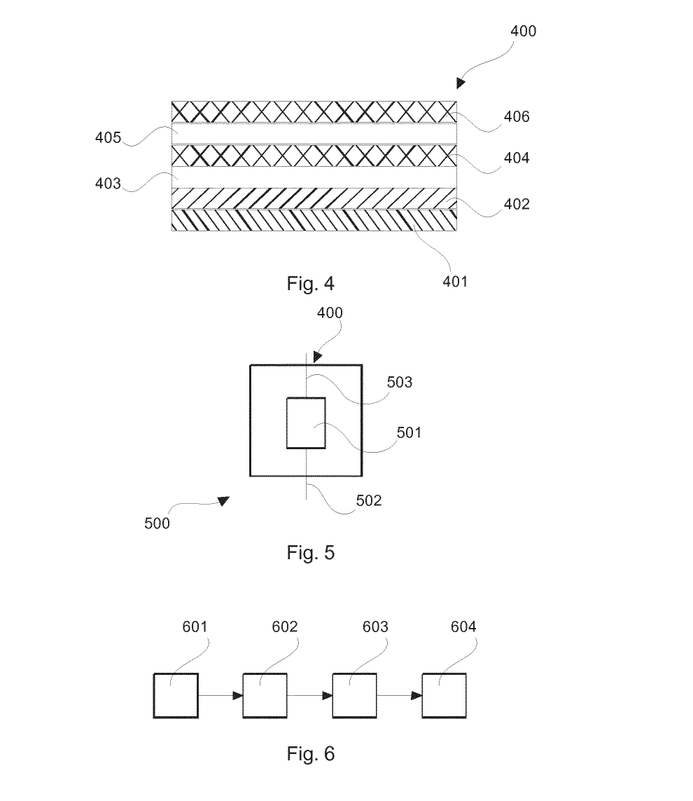

FIG. 4 shows a layer sequence 400 according to an exemplary embodiment of the invention, that exhibits a two-dimensional substrate 401 on which an electrically contactable piezoelectric 402 is arranged. On the piezoelectric 402 there is arranged a layer system that consists of a changing layer sequence of a plurality of anti-ferromagnetic layers 403, 405 and a plurality of magnetostrictive, ferromagnetic layers 404, 406.

FIG. 5 shows a magnetoelectric sensor according to an exemplary embodiment of the invention. The sensor 500 exhibits a layer sequence 400 described above. The electrically contacted piezoelectric is connected by means of the lead 503 to the circuit 501 that receives the signals of the piezoelectric. The circuit 501 can be connected to an external reading device by means of the interface 502.

FIG. 6 shows a flow chart of a method for manufacturing an ME sensor according to an exemplary embodiment of the invention. In step 601 a two-dimensional substrate is coated with an electrically contacted piezoelectric. In step 602 a layer system described above is applied, the direction of the EB field being determined by presetting an external magnetic field. In step 603 it is the measuring direction of the ME sensor that is established as that direction in a plane parallel to the anti-ferromagnetic layer and the magnetostrictive, ferromagnetic layer, in which the piezoelectric coefficient is a maximum in the absence of an external magnetic field. In step 604 the coated two-dimensional substrate is then singulated to form rectangular strips, the long axis of the strips then being intended as the measuring direction and enclosing with the pre-known direction of the EB field the angle αₒₚₜ that is known from preliminary experiments.

It is in addition to be pointed out that “comprising” and “exhibiting” does not exclude any other elements or steps and “a” or “an” does not exclude a multiplicity. It is to be further pointed out that features or steps that were described with reference to one of the exemplary embodiments above can also be used in combination with other features or steps of other exemplary embodiments described above. Reference numerals in the claims are not to be regarded as limitations.

1. A layer system comprising at least one layer sequence comprising:
an anti-ferromagnetic, AFM, layer and
a magnetostrictive, ferromagnetic, FM, layer arranged directly thereon,
wherein the layer sequence has an associated exchange bias, EB, field, the EB-induced degree of magnetization of the FM layer in the absence of an external magnetic field lies within a range between 85% and 100% and
the angle αₒₚₜ, which is enclosed by the EB field direction and the magnetostriction direction, wherein the magnetostriction direction has the maximum piezomagnetic coefficient in the absence of an external magnetic field, within a plane parallel to the AFM layer and the FM layer lies within a range between 10° and 80°.

2. The layer system according to claim 1, characterized in that the angle αₒₚₜ lies within a range between 45° and 75°.

3. The layer system according to claim 2, characterized in that the thickness of the AFM layer of the at least one layer sequence lies within a range of 3 nm to 8 nm.

4. The layer system according to claim 3, characterized in that the thickness of the FM layer of the at least one layer sequence lies within a range of 15 nm to 25 nm.

5. The layer system according to one of claim 4, characterized in that the ratio of thickness of an AFM layer: thickness of an FM layer within a layer sequence lies within a range between 1:8 to 1:2.

6. The layer system according to claim 5, characterized in that the thicknesses of the AFM layers and the thicknesses of the FM layers of different layer sequences within a layer system are identical.

7. The layer system according to claim 6, characterized in that the at least one layer sequence consisting of an AFM layer and an FM layer is embodied as substrate-free.

8. The layer system according to claim 7, characterized in that the AFM layer of the at least one layer sequence consists of or comprises a material selected from the list comprising: Mn₇₀Ir₃₀, Pt₅₀Mn₅₀, Fe₅₀Mn₅₀.

9. The layer system according to claim 8, characterized in that the FM layer of the at least one layer sequence consists of or comprises a material selected from the list comprising: Co₅₀Fe₅₀, Co₄₀Fe₄₀B₂₀, Fe₇₀Co₈B₁₂Si₁₀, Tb₃₅Fe₆₅.

10. A magnetoelectric, ME, sensor for measuring a magnetic field characterized by at least one layer system according to claim 1 in mechanical coupling with at least one piezoelectric layer, wherein the predetermined measuring direction of the sensor substantially encloses the angle αₒₚₜ with the direction of the EB field of the layer system.

11. A method for a production of an ME sensor according to claim 10, comprising at least the following method steps:
i) coating a two-dimensional substrate with an electrically contacted piezoelectric;
ii) applying a layer system according to claim 1, wherein the direction of the EB field is determined by presetting an external magnetic field;
iii) determining a measuring direction of the ME sensor, the measuring direction being in a plane parallel to the anti ferromagnetic direction and the magnetostrictive, ferromagnetic layer, and in which the piezoelectric coefficient is larger than in the direction of the EB field in the absence of an external magnetic field.

12. The method according to claim 11, the measuring direction being established as that direction in a plane parallel to the anti ferromagnetic layer and the magnetostrictive, ferromagnetic layer, in which the piezoelectric coefficient is a maximum in the absence of an external magnetic field.

13. The method according to claim 11, further having the method step:
singulating the coated two-dimensional substrate to rectangular strips, the long axis of the strips extending in the measuring direction and enclosing with the pre-known direction of the EB field the angle αₒₚₜ that is known from preliminary experiments.
